(19) United States
(12) Patent Application Publication
(10) Pub. No.: US 2017/0084797 A1
(43) Pub. Date: Mar. 23, 2017

(54) CONVERSION PHOSPHORS

(71) Applicant: Merck Patent GmbH, Darmstadt (DE)

(72) Inventors: Aleksander ZYCH, Seeheim-Jugenheim (DE); Holger WINKLER, Darmstadt (DE)

(73) Assignee: Merck Patent GmbH, Darmstadt (DE)

(21) Appl. No.: 15/312,046

(22) PCT Filed: Apr. 23, 2015
(86) PCT No.: PCT/EP2015/000841

§ 371 Date: Nov. 17, 2016

(30) Foreign Application Priority Data
May 21, 2014 (EP) 14001792.2

(51) Int. Cl. H01L 33/50; C09K 11/08; H01L 33/32; C09K 11/77

(52) U.S. Cl. CPC H01L 33/502; C09K 11/7792; C09K 11/7793; C09K 11/0883; H01L 33/32

(57) ABSTRACT

The present invention relates to compounds of formula I,

M^{I}M^{II}₃ M^{III}₃M^{IV}₃N₂O₁₂:Eu I

wherein, M^{I}, M^{II}, M^{III}, and M^{IV} have one of the meanings as given in claim 1, to a process of their preparation, the use of these compounds as conversion phosphors or in an emission-converting material, the use of these phosphors in electronic and electro optical devices, such as light emitting diodes (LEDs) and solar cells, and especially, to illumination units comprising at least one of these phosphors.

### TECHNICAL FIELD

The present invention relates to compounds of formula I,

M^{I}M^{II}₃M^{III}₃M^{IV}₃N₂O₁₂:Eu I

wherein, M^{I}, M^{II}, M^{III}, and M^{IV} have one of the meanings as given in claim 1, to a process of their preparation, the use of these compounds as conversion phosphors or in an emission-converting material, the use of these phosphors in electronic and electro optical devices, such as light emitting diodes (LEDs) and solar cells, and especially, to illumination units comprising at least one of these phosphors.

### BACKGROUND ART

White light-emitting diodes (LEDs) exhibit high efficiency, long lifetimes, less environmental impact, absence of mercury, short response times, applicability in final products of various sizes, and many more favorable properties. They are gaining attention as backlight sources for liquid crystal displays, computer notebook monitors, cell phone screens, and in general lighting.

By combining red, green, and blue emitting phosphors with a primary light source, for example a near UV LED, which typically emits light at a wavelength ranging from 280 to 400 nm, it is possible to obtain a tri-color white LED with a good luminescence strength and a superior white color emission.

Typically, a red, a green, and a blue emitting phosphor are firstly mixed in a suitable resin. After that, the resultant gel is provided on a UV-LED chip or a near UV-LED chip, and finally hardened by UV irradiation, annealing, or similar processes. In order to observe an even, white color, while looking at the chip from all angles, the phosphor mixture in the resin should be as homogeneously dispersed as possible. However, it is still difficult to obtain a uniform distribution of the different phosphors in the resin because of their different particle sizes, shapes and/or their density in the resin. Hence, it is advantageous to use less than three phosphors.

However, even by using a mixture of two phosphors, in order to produce white LEDs using UV or near UV-LEDs, it is still difficult to mix phosphors having different sizes, particle shapes, and densities in the resin as uniformly as required. Moreover, the phosphors should not be excited by a wavelength located in the visible range. For instance, if the emission spectrum of the green phosphor overlaps with the excitation spectrum of the red phosphor, then color tuning becomes difficult. Additionally, if a mixture of two or more phosphors is used to produce white LEDs using a blue emitting LED as the primary light source, the excitation wavelength of each phosphor should efficiently overlap with the blue emission wavelength of the LED.

As known to the expert, white LEDs can be also obtained by adding a yellow emitting phosphor to a blue light emitting LED. A suitable and commonly used yellow phosphor in such applications, is yttrium aluminum garnet activated by Ce³⁺, Y₃Al₅O₁₂:Ce³⁺, (YAG:Ce) and described for example in S. Nakamura, G. Fasol, “The Blue Laser Diode”, (1997) p. 343.

Also some ortho-silicates M₂SiO₄:Eu²⁺ (M=Ca, Sr, Ba) are suggested to be used as yellow-orange emitters, as disclosed for example in G. Blasse, et al., Philips Res. Rep., 23 (1968) 189.

Moreover, various nitrides and oxy-nitrides, doped with divalent europium or trivalent cerium ions, such as M₂Si₅N₈:Eu²⁺ (M=Sr, Ba), may be utilized, as described, for example, in H. A. Höppe, H. Lutz, P. Morys, W. Schnick, A. Seilmeier, J. Phys. Chem. Solids 61 (2000) 2001.

However, the aforementioned materials suffer from the fact that the spectral region covered, is not sufficient to produce warm white light.

Accordingly, there is still room for improvements and modern luminescent materials should, preferably exhibit one or more of the following properties:
high colour rendering indices (CRI),
a broad emission band in the range of the VIS-light, especially in the red range of the spectra,
effective excitation by an blue light or near UV emitting primary light source,
broad excitation bands,
high quantum yields,
high phase purities,
high efficiency over a prolonged period of use,
high chemical stability, preferably against humidity or moisture,
high thermal quenching resistivity, and
obtainable by method of production, which is cost efficient and especially suitable for a mass production process.

In view of the cited prior art and the above-mentioned requirements on modern luminescent materials, there is still a considerable demand for alternative materials, which preferably do not exhibit the drawbacks of available phosphors of prior art or even if do so, to a less extent.

### DISCLOSURE OF INVENTION

Surprisingly, the inventors have found that the phosphors of the present invention represent excellent alternatives to already known phosphors of the prior art, and preferably improve one or more of the above-mentioned requirements, or more preferably, fulfil all above-mentioned requirements at the same time.

Besides other beneficial properties, the phosphors according to the present invention exhibit upon excitation by blue or near UV radiation a broad emission peak in the range of the VIS-light, typically in the range from approximately 400 nm to approximately 750 nm, preferably ranging from approximately 425 nm to approximately 725 nm. Moreover, they exhibit high thermal quenching resistivities, have high chemical stabilities, high quantum efficiencies, and high colour rendering properties, especially while being utilized in an LED.

Thus, the present invention relates to compounds of formula I,

M^{I}M^{II}₃ M^{III}₃M^{IV}₃N₂O₁₂:Eu I

wherein
M^{I} denotes one or more elements selected from Y, La, Gd and Lu, preferably La,
M^{II} denotes one or more elements selected from the group of Be, Mg, Ca, Sr, Ba and Zn, preferably Mg, Ca, Sr, and Ba,
M^{III} denotes one or more elements selected from the group of B, Al, and Ga, preferably Al,
M^{IV} denotes one or more elements selected from the Si and Ge.

The invention further relates:
to a method for the production of the compounds according to the present invention,
the use of such compounds as conversion phosphors, converting all or some parts of a blue or near UV radiation into longer wavelength,
mixtures comprising at least one compound according to the present invention, and
the use of a compound according to the present invention or a mixture comprising a compound according to the present invention in electronic and/or electro optical devices, such as light emitting diodes (LEDs) and solar cells,
to electronic and/or electro optical devices, such as light emitting diodes (LEDs) and solar cells, comprising at least one compound of the present invention, and especially
to illumination units comprising at least one compound according to the present invention.

### BRIEF DESCRIPTION OF DRAWINGS

FIG. 1 shows a XRD pattern (measured by the wavelength Cu_{Kα}) of LaBaCa₂Al₃Si₃N₂O₁₂:Eu.

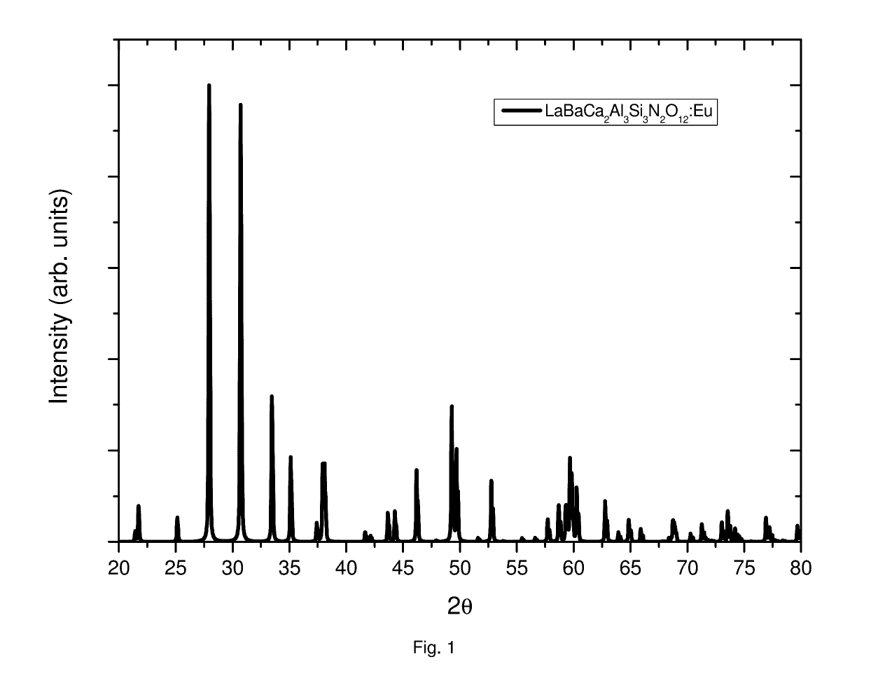

FIG. 2 shows the emission spectra of LaBaCa₂Al₃Si₃N₂O₁₂:Eu, LaBaMg₂Al₃Si₃N₂O₁₂:Eu, and LaBaCa₂Al₃Si₂GeN₂O₁₂:Eu upon excitation with radiation at a wavelength of 390 nm.

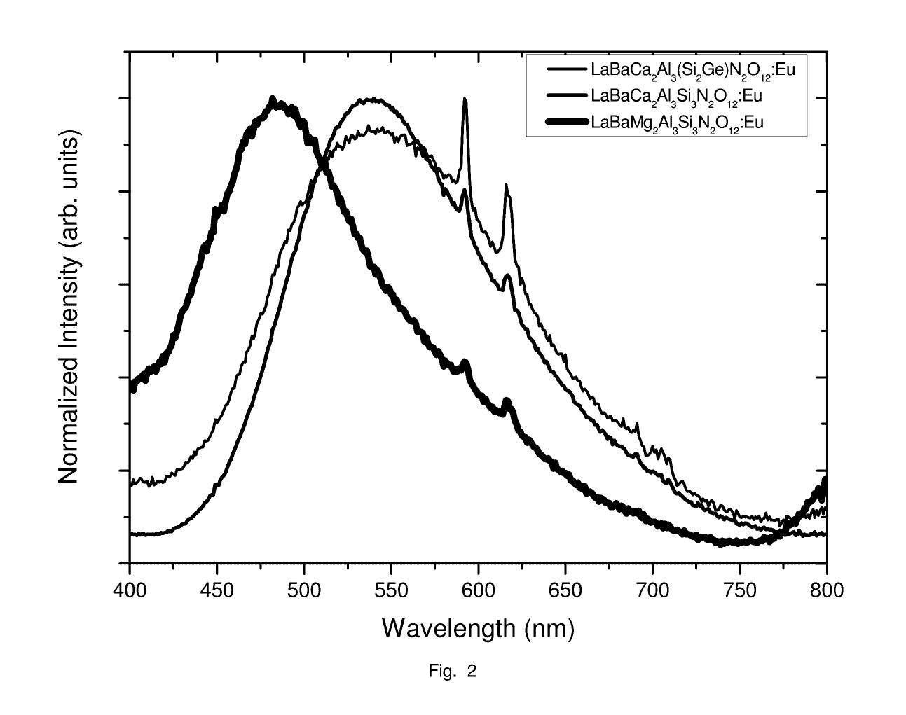

FIG. 3 shows the excitation spectrum of LaBaCa₂Al₃Si₃N₂O₁₂:Eu for emission wavelength of 550 nm.

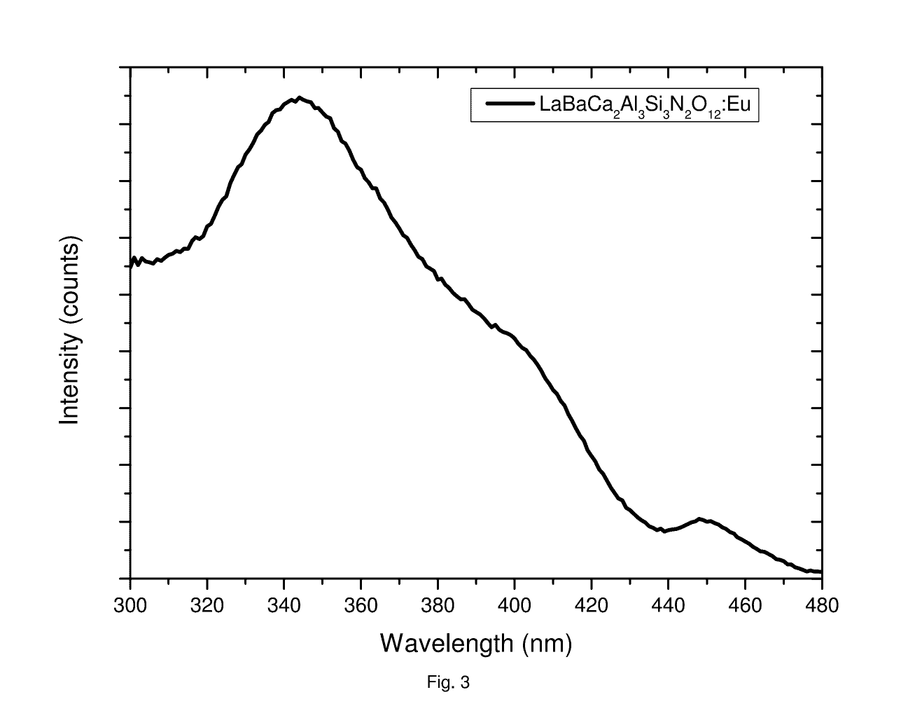

FIG. 4 shows an example LED spectrum of LaBaMg₂Al₃Si₃N₂O₁₂:Eu in a near UV LED emitting primary light source at 395 nm.

FIG. 5 shows an example LED spectrum of LaBaMg₂Al₃Si₂GeN₂O₁₂:Eu in a near UV LED emitting primary light source at 395 nm.

### DETAILED DESCRIPTION OF THE INVENTION

Depending on the conditions of the synthesis and the composition of starting materials as described in more detail below, the compounds according to the present invention may comprise beside Eu²⁺ also amounts of Eu³⁺.

However it is likewise preferred that the compounds according to the present invention are only activated by Eu²⁺. Accordingly, the compounds of formula I are preferably selected from the group of compounds of formula II,

M^{I}M^{II}₃ M^{III}₃M^{IV}₃N₂O₁₂:Eu²⁺ II

wherein
M^{I}, M^{II}, M^{III}, and M^{IV} have one of the meanings as given above in formula I.

More preferably, the compounds of formulae I and II are selected from the group of compounds of formula Ill,

M^{I}M^{II}₃₋ₓ M^{III}₃M^{IV}₃N₂O₁₂:Eu²⁺ₓ III

wherein
M^{I}, M^{II}, M^{III}, and M^{IV} have the same meanings as given in formula II, and 0<x<3, preferably 0<x≦2, more preferably 0<x≦1, especially 0<x≦0.5, in particular 0<x≦0.3.

Further preferred compounds of formulae I or II, are selected from the group of compounds of formula III wherein M^{IV} denotes (Ge_{1-y}Si_{y}) and wherein 0≦y≦1, preferably wherein y denotes 0, 1/3, 2/3 or 1, such as, for example,

M^{I}M^{II}₃₋ₓ M^{III}₃Si₃N₂O₁₂:Eu²⁺ₓ IIIa

M^{I}M^{II}₃₋ₓ M^{III}₃Si₂GeN₂O₁₂:Eu²⁺ₓ IIIb

M^{I}M^{II}₃₋ₓ M^{III}₃Ge₂SiN₂O₁₂:Eu²⁺ₓ IIIc

M^{I}M^{II}₃₋ₓ M^{III}₃Ge₃N₂O₁₂:Eu²⁺ₓ IIId

wherein,
M^{I}, M^{II}, M^{III}, and x have the same meanings as given in formula III,

In another preferred embodiment, the compounds according to the present invention are selected from the group of compounds of formula I or its subformulae, wherein M^{III} denotes Al.

Furthermore, preference is given to compounds, which are selected from the group of compounds of formula I or its subformulae, wherein M^{I} denotes La.

More preferably, the compounds according to the present invention are selected from the group of compounds of the following subformulae,

La M^{II}₃₋ₓ Al₃Si₃N₂O₁₂:Eu²⁺ₓ IVa

La M^{II}₃₋ₓ Al₃Si₂GeN₂O₁₂:Eu²⁺ₓ IVb

La M^{II}₃₋ₓ Al₃Ge₂SiN₂O₁₂:Eu²⁺ₓ IVc

La M^{II}₃₋ₓ Al₃Ge₃N₂O₁₂:Eu²⁺ₓ IVd

wherein, M^{II} and x have one of the meanings as given above in formula III.

In another preferred embodiment, the compounds according to the present invention are selected from the group of compounds of formula I or its subformulae, wherein M^{II} denotes (Ba_{1-z}EA_{z}), in which 0≦z≦1, and EA denotes at least one element selected from Mg, Ca and Sr, such as, for example,

La (Ba_{1-z}Mg_{z})₃₋ₓ Al₃Si₃N₂O₁₂:Eu²⁺ₓ Va

La (Ba_{1-z}Mg_{z})₃₋ₓ Al₃Si₂GeN₂O₁₂:Eu²⁺ₓ Vb

La (Ba_{1-z}Mg_{z})₃₋ₓ Al₃Ge₂SiN₂O₁₂:Eu²⁺ₓ Vc

La (Ba_{1-z}Mg_{z})₃₋ₓ Al₃Ge₃N₂O₁₂:Eu²⁺ₓ Vd

La (Ba_{1-z}Ca_{z})₃₋ₓ Al₃Si₃N₂O₁₂:Eu²⁺ₓ Ve

La (Ba_{1-z}Ca_{z})₃₋ₓ Al₃Si₂GeN₂O₁₂:Eu²⁺ₓ Vf

La (Ba_{1-z}Ca_{z})₃₋ₓ Al₃Ge₂SiN₂O₁₂:Eu²⁺ₓ Vg

La (Ba_{1-z}Ca_{z})₃₋ₓ Al₃Ge₃N₂O₁₂:Eu²⁺ₓ Vh

La (Ba_{1-z}Sr_{z})₃₋ₓ Al₃Si₃N₂O₁₂:Eu²⁺ₓ Vi

La (Ba_{1-z}Sr_{z})₃₋ₓ Al₃Si₂GeN₂O₁₂:Eu²⁺ₓ Vj

La (Ba_{1-z}Sr_{z})₃₋ₓ Al₃Ge₂SiN₂O₁₂:Eu²⁺ₓ Vk

La (Ba_{1-z}Sr_{z})₃₋ₓ Al₃Ge₃N₂O₁₂:Eu²⁺ₓ Vm

wherein 0≦z≦1, preferably z denotes ⅓ or ⅔, and more preferably z denotes ⅔, and 0<x<3.

Typically, the compounds according to the present invention can be excited by artificial or natural radiation sources emitting radiation of a wavelength ranging from approximately 300 nm to approximately 500 nm, preferably from approximately 300 nm to approximately 400 nm.

The compounds according to the present invention typically emit radiation having a wavelength ranging from approximately 400 nm to approximately 750 nm, preferably from approximately 425 nm to approximately 725 nm while being excited by a suitable primary radiation source.

Thus, the compounds according to present invention are especially suitable to convert all or at least some parts of the radiation having a wavelength ranging from approximately 300 nm to approximately 500 nm, preferably of the radiation having a wavelength ranging from approximately 300 nm to approximately 400 nm, into radiation having a longer wavelength, preferably into radiation having a wavelength ranging from approximately 425 nm to approximately 750 nm, more preferably into radiation having a wavelength ranging from approximately 450 nm to approximately 725 nm.

In the context of the present application the term “UV radiation” has the meaning of electromagnetic radiation having a wavelength ranging from approximately 100 nm to approximately 400 nm, unless explicitly stated otherwise.

Additionally, the term “near UV radiation”, has the meaning of electromagnetic radiation in the range of UV radiation having a wavelength ranging from approximately 280 nm to approximately 400 nm, unless explicitly stated otherwise.

Moreover, the term “VIS light or VIS-light region” has the meaning of electromagnetic radiation having a wavelength ranging from approximately 400 nm to approximately 750 nm unless explicitly stated otherwise.

The term “blue radiation” refers to a wavelength between 400 nm and 500 nm.

In this context, the present invention relates also to the use of compounds of formula I or its subformulae as conversion phosphors, or short “phosphors”.

The term “conversion phosphor” and the term “phosphor” are used in the present application in the same manner.

Suitable artificial “radiation sources” or “primary light sources” are commonly known to the expert and will be explained in more detail below.

In the context of the present application, the term “natural radiation sources” means solar irradiation or sunlight.

It is preferred that the emission spectra of the radiation sources and the absorption spectra of the compounds according to the present invention overlap more than 10 area percent, preferable more than 30 area percent, more preferable more than 60 area percent, and most preferable more than 90 area percent.

The term “absorption” means the absorbance of a material, which corresponds to the logarithmic ratio of the radiation falling upon a material, to the radiation transmitted through a material.

The term “emission” means the emission of electromagnetic waves by electron transitions in atoms and molecules.

By varying the composition of the compounds of formulae I or its subformulae with respect to the composition of the parameter M^{II}, it is possible to specifically vary the emission properties. For example, substitution of Ba by Mg leads to an emission having a shorter wavelength, while substitution of Ba by Ca leads to an emission having a longer wavelength.

The compounds according to the present invention preferably exhibit at least one emission peak in the VIS light region, having a FWHM of at least 50 nm or more, preferably 75 nm or more, more preferably 100 nm or more, and most preferably of at least 125 nm or more.

The full width at half maximum (FWHM) is a parameter commonly used to describe the width of a “peak” on a curve or function. It is given by the distance between points on the curve at which the function reaches half its maximum value.

As known to the skilled person, the quantum efficiency of a phosphor decreases as the phosphor size decreases. Preferably, the phosphor exhibits quantum efficiency of at least 80%, more preferably of at least 90%, and the particle size of suitable phosphors particles typically ranges from approximately 50 nm to approximately 100 μm, more preferably from approximately 50 nm to approximately 50 μm, and even more preferably from approximately 50 nm to approximately 25 μm.

The particle size can be defined unambiguously and quantitatively by its diameter. It can be determined by methods known to the skilled artisan such as, for example, dynamic light scattering or static light scattering

Working temperatures in LED applications are typically about 150° C. Preferably, the compounds according to the present invention exhibit high thermal quenching resistivity up to about 100° C. or more, more preferably up to about 150° C. or more, and even more preferably up to about 200° C. or more.

The term “thermal quenching resistivity” means an emission intensity decrease at higher temperature compared to an original intensity at 25° C.

The compounds of the present invention are especially characterized by their high chemical stability. Thus, the compounds of formula I or its subformulae are preferably resistant to oxidation and hydrolysis.

In accordance with the present invention, the compounds of formula I can be present in the form of a pure substance or a mixture.

The present invention therefore also relates to a mixture comprising at least two compounds of the formula I, as defined above, preferably wherein at least one compound is activated by Eu³⁺ and the other compound is activated by Eu²⁺.

It is preferred in accordance with the invention that the compound of formula I comprising Eu³⁺ is a side-product of the preparation of the compound of the formula II and for this not to adversely affect the application-relevant optical properties of the compound of the formula II.

The compound of formula II is usually present in such mixtures in a proportion by weight in the range 30-95% by weight, preferably in the range 50-90% by weight and particularly preferably in the range 60-88% by weight.

The invention also relates to a process for the synthesis of a compound of the formula I, comprising at least the following steps:
a) mixing of suitable starting materials selected from binary nitrides, halides, carbonates and oxides or corresponding reactive forms thereof, and
b) thermally treatment of a mixture of step a) under reductive conditions.

The starting materials for the preparation of the compounds according to the present invention are commercially available and suitable processes for the preparation of the compounds according to the present invention can be summarized as a solid-state diffusion process.

In the context of the present application, the term “solid state diffusion process” refers to any mixing and firing method or solid-phase method, comprising the steps mixing suitable starting materials and thermal treatment of the mixture under reductive conditions

In the process according to the invention for the preparation of phosphors according to the invention, suitable starting materials are selected from binary nitrides, halides and oxides or corresponding reactive forms thereof are mixed in a step a), and the mixture is thermally treated under reductive conditions in a step b).

In the above-mentioned thermal treatment, it is preferred for this to be carried out at least partly under reducing conditions.

In step b), the reaction is usually carried out at a temperature above 800° C., preferably at a temperature above 1000° C. and particularly preferably in the range from 1000° C. to 1400° C.

The reductive conditions here are established, for example, using ammonia, carbon monoxide, forming gas or hydrogen or at least vacuum or an oxygen-deficient atmosphere, preferably in a stream of nitrogen, preferably in a stream of N₂/H₂ and particularly preferably in a stream of N₂/H₂/NH₃.

If it is intended to prepare the compounds of the formula I in pure form, this can be carried out either via precise control of the starting-material stoichiometry or by mechanical separation of the crystals of the compounds of the formula I.

The separation can be carried out, for example, via the different density, particle shape or particle size by separation methods known to the person skilled in the art.

Preferably, the process comprises the steps
a) mixing at least one salt containing Eu;
   one or more salts comprising at least one element selected from Be, Mg, Ca, Sr, Ba, and Zn;
   one or more salts comprising at least one element selected from B, Al, and Ga;
   one or more compound comprising at least one element selected from Si and Ge, such as, for example SiO₂ or GeO₂;
   Si₃N₄ or Ge₃N₄; and
   one or more salts comprising at least one element selected from Y, La, Gd and Lu;
   at a predetermined molar ratio;
b) performing a heat treatment on the mixture in a temperature range from 700 to 1500° C. under a reductive atmosphere.

Fluxing agents might also be used in the process. Suitable fluxing agents are typically chosen from the generally accepted and used fluxes in the typical amounts accepted for the fluxes in the process in accordance with the present invention. Preferred fluxing agents are selected from the group of corresponding fluorides, chlorides, bromides, iodides, sulfates, carbonates and/or oxides, as well as combinations of these fluxing agents in any ratio and any combination.

In a further preferred embodiment, the utilized phosphors have a continuous surface coating comprising and preferably consisting of SiO₂, TiO₂, Al₂O₃, ZnO, ZrO₂, Y₂O₃, B₂O₃ BN, AlₓSi_{y}O_{z}, Al₂Si₄O₁₀(OH)₂) and/or MgO or mixed oxides thereof. This surface coating has the advantage that, through a suitable grading of the refractive indices of the coating materials, the refractive index can be matched to the environment. In this case, the scattering of light at the surface of the phosphor is reduced and a greater proportion of the light can penetrate into the phosphor and be absorbed and converted therein. In addition, the refractive index-matched surface coating enables more light to be coupled out of the phosphor since total internal reflection is reduced.

In addition, a continuous layer is advantageous if the phosphor has to be encapsulated. This may be necessary in order to counter sensitivity of the phosphor or parts thereof to diffusing water or other materials in the immediate environment. A further reason for encapsulation with a closed shell is thermal decoupling of the actual phosphor from the heat generated in the chip. This heat results in a reduction in the fluorescence light yield of the phosphor and may also influence the colour of the fluorescence light. Finally, a coating of this type enables the efficiency of the phosphor to be increased by preventing lattice vibrations arising in the phosphor from propagating to the environment.

In addition, it is preferred that the utilized phosphors have a porous surface coating comprising and preferably consisting of SiO₂, TiO₂, Al₂O₃, ZnO, ZrO₂ and/or Y₂O₃ or mixed oxides thereof or of the phosphor composition. These porous coatings offer the possibility of further reducing the refractive index of a single layer. Porous coatings of this type can be produced by three conventional methods, as described e.g. in WO 03/027015, which is incorporated in its full scope into the context of the present application by way of reference: the etching of glass (for example soda-lime glasses (see U.S. Pat. No. 4,019,884)), the application of a porous layer, and the combination of a porous layer and an etching operation.

In a further preferred embodiment, the utilized phosphors have a surface which carries functional groups which facilitate chemical bonding to the environment, preferably consisting of epoxy or silicone resin. These functional groups can be, for example, esters or other derivatives which are bonded via oxo groups and are able to form links to constituents of the binders based on epoxides and/or silicones. Surfaces of this type have the advantage that homogeneous incorporation of the phosphors into the binder is facilitated. Furthermore, the rheological properties of the phosphor/binder system and also the pot lives can thereby be adjusted to a certain extent. Processing of the mixtures is thus simplified.

Since the phosphor layer according to the invention applied to the LED chip preferably consists of a mixture of silicone and homogeneous phosphor particles which is applied by bulk casting, and the silicone has a surface tension, this phosphor layer is not uniform at a microscopic level or the thickness of the layer is not constant throughout. This is generally also the case if the phosphor is not applied by the bulk-casting process, but instead in the so-called chip-level conversion process, in which a highly concentrated, thin phosphor layer is applied directly to the surface of the chip with the aid of electrostatic methods.

With the aid of the above-mentioned process, it is possible to produce any desired outer shapes of the phosphor particles, such as spherical particles, flakes and structured materials and ceramics.

The preparation of flake-form phosphors as a further preferred embodiment is carried out by conventional processes from the corresponding metal salts and/or rare-earth salts. The preparation process is described in detail in EP 763573 and DE 102006054331, which are incorporated in their full scope into the context of the present application by way of reference. These flake-form phosphors can be prepared by coating a natural or synthetically prepared, highly stable support or a substrate comprising, for example, mica, SiO₂, Al₂O₃, ZrO₂, glass or TiO₂ flakes which has a very large aspect ratio, an atomically smooth surface and an adjustable thickness with a phosphor layer by a precipitation reaction in aqueous dispersion or suspension. Besides mica, ZrO₂, SiO₂, Al₂O₃, glass or TiO₂ or mixtures thereof, the flakes may also consist of the phosphor material itself or be built up from one material. If the flake itself merely serves as support for the phosphor coating, the latter must consist of a material which is transparent to the primary radiation of the LED, or absorbs the primary radiation and transfers this energy to the phosphor layer. The flake-form phosphors are dispersed in a resin (for example silicone or epoxy resin), and this dispersion is applied to the LED chip. The flake-form phosphors can be prepared on a large industrial scale in thicknesses of 50 nm to about 20 μm, preferably between 150 nm and 5 μm. The diameter here is 50 nm to 20 μm.

It generally has an aspect ratio (ratio of the diameter to the particle thickness) of 1:1 to 400:1 and in particular 3:1 to 100:1.

The flake dimensions (length×width) are dependent on the arrangement. Flakes are also suitable as centres of scattering within the conversion layer, in particular if they have particularly small dimensions.

The surface of the flake-form phosphor according to the invention facing the LED chip can be provided with a coating which has an antireflection action with respect to the primary radiation emitted by the LED chip. This results in a reduction in back-scattering of the primary radiation, enabling the latter to be coupled better into the phosphor body according to the invention.

Suitable for this purpose are, for example, coatings of matched refractive index, which must have a following thickness d: d=[wavelength of the primary radiation of the LED chip/(4*refractive index of the phosphor ceramic)], see, for example, Gerthsen, Physik [Physics], Springer Verlag, 18th Edition, 1995. This coating may also consist of photonic crystals, which also includes structuring of the surface of the flake-form phosphor in order to achieve certain functionalities.

The production of the phosphors according to the invention in the form of ceramic bodies is carried out analogously to the process described in DE 102006037730 (Merck), which is incorporated in its full scope into the context of the present application by way of reference. In this process, the phosphor is prepared by wet-chemical methods by mixing the corresponding starting materials and dopants, subsequently subjected to isostatic pressing and applied directly to the surface of the chip in the form of a homogeneous, thin and non-porous flake. There is thus no location-dependent variation of the excitation and emission of the phosphor, which means that the LED provided therewith emits a homogeneous light cone of constant colour and has high light output. The ceramic phosphor bodies can be produced on a large industrial scale, for example, as flakes in thicknesses of a few 100 nm to about 500 μm. The flake dimensions (length×width) are dependent on the arrangement. In the case of direct application to the chip, the size of the flake should be selected in accordance with the chip dimensions (from about 100 μm*100 μm to several mm²) with a certain oversize of about 10% to 30% of the chip surface with a suitable chip arrangement (for example flip-chip arrangement) or correspondingly. If the phosphor flake is installed over a finished LED, the entire exiting light cone passes through the flake.

The side surfaces of the ceramic phosphor body can be coated with a light metal or noble metal, preferably aluminium or silver. The metal coating has the effect that light does not exit laterally from the phosphor body. Light exiting laterally can reduce the luminous flux to be coupled out of the LED. The metal coating of the ceramic phosphor body is carried out in a process step after the isostatic pressing to give rods or flakes, where the rods or flakes can optionally be cut to the requisite size before the metal coating. To this end, the side surfaces are wetted, for example, with a solution comprising silver nitrate and glucose and subsequently exposed to an ammonia atmosphere at elevated temperature. A silver coating, for example, forms on the side surfaces in the process.

Alternatively, current less metallisation processes are also suitable, see, for example, Hollemann-Wiberg, Lehrbuch der Anorganischen Chemie [Textbook of Inorganic Chemistry], Walter de Gruyter Verlag or Ullmanns Enzyklopädie der chemischen Technologie [Ullmann's Encyclopaedia of Chemical Technology].

The ceramic phosphor body can, if necessary, be fixed to the baseboard of an LED chip using a water-glass solution.

In a further embodiment, the ceramic phosphor body has a structured (for example pyramidal) surface on the side opposite an LED chip. This enables as much light as possible to be coupled out of the phosphor body. The structured surface on the phosphor body is produced by carrying out the isostatic pressing using a compression mould having a structured pressure plate and thus embossing a structure into the surface. Structured surfaces are desired if the aim is to produce the thinnest possible phosphor bodies or flakes. The pressing conditions are known to the person skilled in the art (see J. Kriegsmann, Technische keramische Werkstoffe [Industrial Ceramic Materials], Chapter 4, Deutscher Wirtschaftsdienst, 1998). It is important that the pressing temperatures used are ⅔ to ⅚ of the melting point of the substance to be pressed.

The phosphors of the present invention are of good LED quality.

In the context of this application, the LED quality is determined by commonly known parameters, such as the color rendering index (CRI), the Correlated Color Temperature (CCT), the lumen equivalent or absolute lumen, and the color point in CIE x and y coordinates.

The Color Rendering Index (CRI), as known to the expert, is a unit less photometric size, which compares the color fidelity of an artificial light source to that of a reference light source according to the Technical Report CIE 13.3-1995 (the reference light sources exhibit a CRI of 100).

The Correlated Color Temperature (CCT), as known to the expert, is a photometric variable having the unit Kelvin. The higher the number, the greater the blue component of the light and the colder the white light of an artificial light source appears to the viewer. The CCT follows the concept of the black light blue lamp, which color temperature describes the so-called Planckian locus in the CIE chromaticity diagram.

The lumen equivalent, as known to the expert, is a photometric variable having the unit the Im/W. The lumen equivalent describes the size of the photometric luminous flux of a light source at a specific radiometric radiation power of 1 W. The higher the lumen equivalent at a given radiometric radiation power is, the brighter this light source appears to a human observer, compared with another light source of the same radiometric radiation power, but with a lower lumen equivalent value.

The lumen, as known to the expert, is photometric variable, which describes the luminous flux of a light source, which is a measure of the total radiation emitted by a light source in the VIS region (Light having a wavelength ranging from approximately 380 to approximately 800 nm), which is weighted by the sensitivity of the human eye at different wavelengths. The greater the light output, the brighter the light source appears to the observer.

CIE x and CIE y are the coordinates of the CIE chromaticity diagram (here 1931 2°-standard observer), which describes the color of a light source.

All of the above variables can be calculated from the emission spectra of the light source by methods known to the expert.

The phosphors of the present invention show especially favorable values for the conversion efficiency while being utilized in an pc-LED.

The term “conversion efficiency” relates to the quotient of the radiometric flux of the pc-LED (LED-die with phosphor layer) φ_{pc-LED} divided by the radiometric flux of the aforementioned LED-die Φ_{LED-die} without the phosphor layer multiplied with 100%: Φ_{pc-LED}/Φ_{LED-die}×100%. The higher the conversion efficiency is, the better is the light conversion of the phosphor layer and the lower are the losses due to the light conversion process in the phosphor layer.

The phosphors according to the present invention can be used as obtained or in a mixture with other phosphors. Accordingly, the present invention also relates to an emission-converting material comprising one or more compounds according to the present invention and one or more phosphors having another chemical composition.

Suitable phosphors for a mixture or an emission-converting material according to the present invention are, for example: Ba₂SiO₄:Eu²⁺, BaSi₂O₅:Pb²⁺, BaₓSr₁₋ₓF₂:Eu²⁺, BaSrMgSi₂O₇:Eu²⁺, BaTiP₂O₇, (Ba,Ti)₂P₂O₇:Ti, Ba₃WO₆:U, BaY₂F₈:Er³⁺, Yb⁺, Be₂SiO₄:Mn²⁺, Bi₄Ge₃O₁₂, CaAl₂O₄:Ce³⁺, CaLa₄O₇:Ce³⁺, CaAl₂O₄:Eu²⁺, CaAl₂O₄:Mn²⁺, CaAl₄O₇:Pb²⁺, Mn²⁺, CaAl₂O₄:Tb³⁺, Ca₃Al₂Si₃O₁₂:Ce³⁺, Ca₃Al₂Si₃Oi₂:Ce³⁺, Ca₃Al₂Si₃O, ₂:Eu²⁺, Ca₂B₅O₉Br:Eu²⁺, Ca₂B₅O₉Cl:Eu²⁺, Ca₂B₅O₉Cl:Pb²⁺, CaB₂O₄:Mn²⁺, Ca₂B₂O₅:Mn²⁺, CaB₂O₄:Pb²⁺, CaB₂P₂O₉:Eu²⁺, Ca₅B₂SiO₁₀:Eu³⁺, Ca_{0.5}Ba_{0.5}Al₁₂O₁₉:Ce³⁺, Mn²⁺, Ca₂Ba₃(PO₄)₃Cl:Eu²⁺, CaBr₂:Eu²⁺ in SiO₂, CaCl₂:Eu²⁺ in SiO₂, CaCl₂:Eu²⁺, Mn²⁺ in SiO₂, CaF₂:Ce³⁺, CaF₂:Ce³⁺, Mn²⁺, CaF₂:Ce³⁺, Tb³⁺, CaF₂:Eu²⁺, CaF₂:Mn²⁺, CaF₂:U, CaGa₂O₄:Mn²⁺, CaGa₄O₇:Mn²⁺, CaGa₂S₄:Ce³⁺, CaGa₂S₄:Eu²⁺, CaGa₂S₄:Mn²⁺, CaGa₂S₄:Pb²⁺, CaGeO₃:Mn²⁺, CaI₂:Eu²⁺ in SiO₂, CaI₂:Eu²⁺, Mn²⁺ in SiO₂, CaLaBO₄:Eu³⁺, CaLaB₃O₇:Ce³⁺, Mn²⁺, Ca₂La₂BO_{6.5}:Pb²⁺, Ca₂MgSi₂O₇, Ca₂MgSi₂O₇:Ce³⁺, CaMgSi₂O₆:Eu²⁺, Ca₃MgSi₂O₈:Eu²⁺, Ca₂MgSi₂O₇:Eu²⁺, CaMgSi₂O₆:Eu²⁺, Mn²⁺, Ca₂MgSi₂O₇:Eu²⁺, Mn²⁺, CaMoO₄, CaMoO₄:Eu³⁺, CaO:Bi³⁺, CaO:Cd²⁺, CaO:Cu⁺, CaO:Eu³⁺, CaO:Eu³⁺, Na⁺, CaO:Mn²⁺, CaO:Pb²⁺, CaO:Sb³⁺, CaO:Sm³⁺, CaO:Tb³⁺, CaO:Tl, CaO:Zn²⁺, Ca₂P₂O₇:Ce³⁺, α-Ca₃(PO₄)₂:Ce³⁺, β-Ca₃(PO₄)₂:Ce³⁺, Ca₅(PO₄)₃Cl:Eu²⁺, Ca₅(PO₄)₃Cl:Mn²⁺, Ca₅(PO₄)₃Cl:Sb³⁺, Ca₅(PO₄)₃Cl:Sn²⁺, β-Ca₃(PO₄)₂:Eu²⁺, Mn²⁺, Ca₅(PO₄)₃F:Mn²⁺, Caₛ(PO₄)₃F:Sb³⁺, Caₛ(PO₄)₃F:Sn²⁺, α-Ca₃(PO₄)₂:Eu²⁺, β-Ca₃(PO₄)₂:Eu²⁺, Ca₂P₂O₇:Eu²⁺, Ca₂P₂O₇:Eu²⁺, Mn²⁺, CaP₂O₆:Mn²⁺, α-Ca₃(PO₄)₂:Pb²⁺, α-Ca₃(PO₄)₂:Sn²⁺, β-Ca₃(PO₄)₂:Sn²⁺, β-Ca₂P₂O₇:Sn, Mn, α-Ca₃(PO₄)₂:Tr, CaS:Bi³⁺, CaS:Bi³⁺, Na, CaS:Ce³⁺, CaS:Eu²⁺, CaS:Cu⁺, Na⁺, CaS:La³⁺, CaS:Mn²⁺, CaSO₄:Bi, CaSO₄:Ce³⁺, CaSO₄:Ce³⁺, Mn²⁺, CaSO₄:Eu²⁺, CaSO₄:Eu²⁺, Mn²⁺, CaSO₄:Pb²⁺, CaS:Pb²⁺, CaS:Pb²⁺, Cl, CaS:Pb²⁺, Mn²⁺, CaS:Pr³⁺, Pb²⁺, Cl, CaS:Sb³⁺, CaS:Sb³⁺, Na, CaS:Sm³⁺, CaS:Sn²⁺, CaS:Sn²⁺, F, CaS:Tb³⁺, CaS:Tb³⁺, Cl, CaS:Y³⁺, CaS:Yb²⁺, CaS:Yb²⁺, Cl, CaSiO₃:Ce³⁺, Ca₃SiO₄Cl₂:Eu²⁺, Ca₃SiO₄Cl₂:Pb²⁺, CaSiO₃:Eu²⁺, CaSiO₃:Mn²⁺, Pb, CaSiO₃:Pb²⁺, CaSiO₃:Pb²⁺, Mn²⁺, CaSiO₃:Ti⁴⁺, CaSr₂(PO₄)₂:Bi³⁺, β-(Ca,Sr)₃(PO₄)₂:Sn²⁺Mn²⁺, CaTi_{0.9}Al_{0.1}O₃:Bi³⁺, CaTiO₃:Eu³⁺, CaTiO₃:Pr³⁺, Ca₅(VO₄)₃Cl, CaWO₄, CaWO₄:Pb²⁺, CaWO₄:W, Ca₃WO₆:U, CaYAlO₄:Eu³⁺, CaYBO₄:Bi³⁺, CaYBO₄:Eu³⁺, CaYB_{0.8}O_{3.7}:Eu³⁺, CaY₂ZrO₆:Eu³⁺, (Ca,Zn,Mg)₃(PO₄)₂:Sn, CeF₃, (Ce,Mg)BaAl₁₁O₁₈:Ce, (Ce,Mg)SrAl₁₁O₁₈:Ce, CeMgAl₁₁O₁₉:Ce:Tb, Cd₂B₆O₁₁:Mn²⁺, CdS:Ag⁺, Cr, CdS:In, CdS:In, CdS:In, Te, CdS:Te, CdWO₄, CsF, CsI, CsI:Na⁺, CsI:Tl, (ErCl₃)_{0.25}(BaCl₂)_{0.75}, GaN:Zn, Gd₃Ga₅O₁₂:Cr³⁺, Gd₃Ga₅O₁₂:Cr, Ce, GdNba₄:Bi³⁺, Gd₂O₂S:Eu³⁺, Gd₂O₂Pr³⁺, Gd₂O₂S:Pr, Ce, F, Gd₂O₂S:Tb³⁺, Gd₂SiO₅:Ce³⁺, KAl₁₁O₁₇:Tl⁺, KGa₁₁O₁₇:Mn²⁺, K₂La₂Ti₃O₁₀:Eu, KMgF₃:Eu²⁺, KMgF₃:Mn²⁺, K₂SiF₆:Mn⁴⁺, LaAl₃B₄O₁₂:Eu³⁺, LaAlB₂O₆:Eu³⁺, LaAlO₃:Eu³⁺, LaAlO₃:Sm³⁺, LaAsO₄:Eu³⁺, LaBr₃:Ce³⁺, LaBO₃:Eu³⁺, (La,Ce,Tb)PO₄:Ce:Tb, LaCl₃:Ce³⁺, La₂O₃:Bi³⁺, LaOBr:Tb³⁺, LaOBr:Tm³⁺, LaOCl:Bi³⁺, LaOCl:Eu³⁺, LaOF:Eu³⁺, La₂O₃:Eu³⁺, La₂O₃:Pr³⁺, La₂O₂S:Tb³⁺, LaPO₄:Ce³⁺, LaPO₄:Eu³⁺, LaSiO₃Cl:Ce³⁺, LaSiO₃Cl:Ce³⁺, Tb³⁺, LaVO₄:Eu³⁺, La₂W₃O₁₂:Eu³⁺, LiAlF₄:Mn²⁺, LiAl₅O₈:Fe³⁺, LiAlO₂:Fe³⁺, LiAlO₂:Mn²⁺, LiAl₅O₈:Mn²⁺, Li₂CaP₂O₇:Ce³⁺, Mn²⁺, LiCeBa₄Si₄O₁₄:Mn²⁺, LiCeSrBa₃Si₄O₁₄:Mn²⁺, LiInO₂:Eu³⁺, LiInO₂:Sm³⁺, LiLaO₂:Eu³⁺, LuAlO₃:Ce³⁺, (Lu,Gd)₂SiO₅:Ce³⁺, Lu₂SiO₅:Ce³⁺, Lu₂Si₂O₇:Ce³⁺, LuTaO₄:Nb⁵⁺, Lu₁, YₓAlO₃:Ce³⁺, MgAl₂O₄:Mn²⁺, MgSrAl₁₀O₁₇:Ce, MgB₂O₄:Mn²⁺, MgBa₂(PO₄)₂:Sn²⁺, MgBa₂(PO₄)₂:U, MgBaP₂O₇:Eu²⁺, MgBaP₂O₇:Eu²⁺, Mn²⁺, MgBa₃Si₂O₈:Eu²⁺, MgBa(SO₄)₂:Eu²⁺, Mg₃Ca₃(PO₄)₄:Eu²⁺, MgCaP₂O₇:Mn²⁺, Mg₂Ca(SO₄)₃:Eu²⁺, Mg₂Ca(SO₄)₃:Eu²⁺, Mn², MgCeAlₙO₁₉:Tb³⁺, Mg₄(F)GeO₆:Mn²⁺, Mg₄(F)(Ge,Sn)O₆:Mn²⁺, MgF₂:Mn²⁺, MgGa₂O₄:Mn²⁺, Mg₈Ge₂Oᵢᵢ F₂:Mn⁴⁺, MgS:Eu²⁺, MgSiO₃:Mn²⁺, Mg₂SiO₄:Mn²⁺, Mg₃SiO₃F₄:Ti⁴⁺, MgSO₄:Eu²⁺, MgSO₄:Pb²⁺, MgSrBa₂Si₂O₇:Eu²⁺, MgSrP₂O₇:Eu²⁺, MgSr₅(PO₄)₄:Sn²⁺, MgSr₃Si₂O₈:Eu²⁺, Mn²⁺, Mg₂Sr(SO₄)₃:Eu²⁺, Mg₂TiO₄:Mn⁴⁺, MgWO₄, MgYBO₄:Eu³⁺, Na₃Ce(PO₄)₂:Tb³⁺, NaI:Tl, Na_{1.23}K_{0.42}Eu_{0.12}TiSi₄O₁₁:Eu³⁺, Na_{1.23}K_{0.42}Eu_{0.12}TiSi₅O₁₃.xH₂O:Eu³⁺, Na_{1.29}K_{0.46}Er_{0.08}TiSi₄O₁₁:Eu³⁺, Na₂Mg₃Al₂Si₂O₁₀:Tb, Na(Mg₂₋ₓMnₓ)LiSi₄O₁₀F₂:Mn, NaYF₄:Er³⁺, Yb³⁺, NaYO₂:Eu³⁺, P46(70%)+P47 (30%), SrAl₁₂O₁₉:Ce³⁺, Mn²⁺, SrAl₂O₄:Eu²⁺, SrAl₄O₇:Eu³⁺, SrAl₁₂O₁₉:Eu²⁺, SrAl₂S₄:Eu²⁺, Sr₂B₅O₉Cl:Eu²⁺, SrB₄O₇:Eu²⁺(F,Cl,Br), SrB₄O₇:Pb²⁺, SrB₄O₇:Pb²⁺, Mn²⁺, SrB₈O₁₃:Sm²⁺, SrₓBa_{y}Cl_{z}Al₂O_{4-z/2}: Mn²⁺, Ce³⁺, SrBaSiO₄:Eu²⁺, Sr(Cl,Br,I)₂:Eu²⁺ in SiO₂, SrCl₂:Eu²⁺ in SiO₂, Sr₅Cl(PO₄)₃:Eu, Sr_{w}FₓB₄O_{6.5}:Eu²⁺, Sr_{w}FₓB_{y}O_{z}:Eu²⁺, Sm²⁺, SrF₂:Eu²⁺, SrGa₁₂O₁₉:Mn²⁺, SrGa₂S₄:Ce³⁺, SrGa₂S₄:Eu²⁺, SrGa₂S₄:Pb²⁺, SrIn₂O₄:Pr³⁺, Al³⁺, (Sr,Mg)₃(PO₄)₂:Sn, SrMgSi₂O₆:Eu²⁺, Sr₂MgSi₂O₇:Eu²⁺, Sr₃MgSi₂O₈:Eu²⁺, SrMoO₄:U, SrO.3B₂O₃:Eu²⁺, Cl, β-SrO.3B₂O₃:Pb²⁺, β-SrO.3B₂O₃:Pb²⁺, Mn²⁺, α-SrO.3B₂O₃:Sm²⁺, Sr₆P₅BO₂₀:Eu, Sr₅(PO₄)₃Cl:Eu²⁺, Sr₅(PO₄)₃Cl:Eu²⁺, Pr³⁺, Sr₅(PO₄)₃Cl:Mn²⁺, Sr₅(PO₄)₃Cl:Sb³⁺, Sr₂P₂O₇:Eu²⁺, β-Sr₃(PO₄)₂:Eu²⁺, Sr₅(PO₄)₃F:Mn²⁺, Sr₅(PO₄)₃F:Sb³⁺, Sr₅(PO₄)₃F:Sb³⁺, Mn²⁺, Sr₅(PO₄)₃F:Sn²⁺, Sr₂P₂O₇:Sn²⁺, β-Sr₃(PO₄)₂:Sn²⁺, β-Sr₃(PO₄)₂:Sn²⁺, Mn²⁺(Al), SrS:Ce³⁺, SrS:Eu²⁺, SrS:Mn²⁺, SrS:Cu⁺, Na, SrSO₄:Bi, SrSO₄:Ce³⁺, SrSO₄:Eu²⁺, SrSO₄:Eu²⁺, Mn²⁺, Sr₅Si₄O₁₀Cl₆:Eu²⁺, Sr₂SiO₄:Eu²⁺, SrTiO₃:Pr³⁺, SrTiO₃:Pr³⁺, Al³⁺, Sr₃WO₆:U, SrY₂O₃:Eu³⁺, ThO₂:Eu³⁺, ThO₂:Pr³⁺, ThO₂:Tb³⁺, YAl₃B₄O₁₂:Bi³⁺, YAl₃B₄O₁₂:Ce³⁺, YAl₃B₄O₁₂:Ce³⁺, Mn, YAl₃B₄O₁₂:Ce³⁺, Tb³⁺, YAl₃B₄O₁₂:Eu³⁺, YAl₃B₄O₁₂:Eu³⁺, Cr³⁺, YAl₃B₄O₁₂:Th⁴⁺, Ce³⁺, Mn²⁺, YAlO₃:Ce³⁺, Y₃Al₅O₁₂:Ce³⁺, Y₃Al₅O₁₂:Cr³⁺, YAlO₃:Eu³⁺, Y₃Al₅O₁₂:Eu^{3r}, Y₄Al₂O₉:Eu³⁺, Y₃Al₅O₁₂:Mn⁴⁺, YAlO₃:Sm³⁺, YAlO₃:Tb³⁺, Y₃Al₅O₁₂:Tb³⁺, YAsO₄:Eu³⁺, YBO₃:Ce³⁺, YBO₃:Eu³⁺, YF₃:Er³⁺, Yb³⁺, YF₃:Mn²⁺, YF₃:Mn²⁺, Th⁴⁺, YF₃:Tm³⁺, Yb³⁺, (Y,Gd)BO₃:Eu, (Y,Gd)BO₃:Tb, (Y,Gd)₂O₃:Eu³⁺, Y_{1.34}Gd_{0.60}O₃(Eu,Pr), Y₂O₃:Bi³⁺, YOBrEu³⁺, Y₂O₃:Ce, Y₂O₃:Er³⁺, Y₂O₃:Eu³⁺(YOE), Y₂O₃:Ce³⁺, Tb³⁺, YOCl:Ce³⁺, YOCl:Eu³⁺, YOF:Eu³⁺, YOF:Tb³⁺, Y₂O₃:Ho³⁺, Y₂O₂S:Eu³⁺, Y₂O₂S:Pr³⁺, Y₂O₂S:Tb³⁺, Y₂O₃:Tb³⁺, YPO₄:Ce³⁺, YPO₄:Ce³⁺, Tb³⁺, YPO₄:Eu³⁺, YPO₄:Mn²⁺, Th⁴⁺, YPO₄:V⁵⁺, Y(P,V)O₄:Eu, Y₂SiO₅:Ce³⁺, YTaO₄, YTaO₄:Nb⁵⁺, YVO₄:Dy³⁺, YVO₄:Eu³⁺, ZnAl₂O₄:Mn²⁺, ZnB₂O₄:Mn²⁺, ZnBa₂S₃:Mn²⁺, (Zn,Be)₂SiO₄:Mn²⁺, Zn_{0.4}Cd_{0.6}S:Ag, Zn_{0.6}Cd_{0.4}S:Ag, (Zn,Cd)S:Ag, Cl, (Zn,Cd)S:Cu, ZnF₂:Mn²⁺, ZnGa₂O₄, ZnGa₂O₄:Mn²⁺, ZnGa₂S₄:Mn²⁺, Zn₂GeO₄:Mn²⁺, (Zn,Mg)F₂:Mn²⁺, ZnMg₂(PO₄)₂:Mn²⁺, (Zn,Mg)₃(PO₄)₂:Mn²⁺, ZnO:Al³⁺, Ga³⁺, ZnO:Bi³⁺, ZnO:Ga³⁺, ZnO:Ga, ZnO—CdO:Ga, ZnO:S, ZnO:Se, ZnO:Zn, ZnS:Ag⁺, Cl⁻, ZnS:Ag, Cu, Cl, ZnS:Ag, Ni, ZnS:Au, In, ZnS—CdS (25-75), ZnS—CdS (50-50), ZnS—CdS (75-25), ZnS—CdS:Ag, Br, Ni, ZnS—CdS:Ag+, Cl, ZnS—CdS:Cu, Br, ZnS—CdS:Cu, I, ZnS:Cl⁻, ZnS:Eu²⁺, ZnS:Cu, ZnS:Cu⁺, Al³⁺, ZnS:Cu⁺, Cl⁻, ZnS:Cu, Sn, ZnS:Eu²⁺, ZnS:Mn²⁺, ZnS:Mn, Cu, ZnS:Mn²⁺, Te²⁺, ZnS:P, ZnS:P³⁻, Cl⁻, ZnS:Pb²⁺, ZnS:Pb²⁺, Cl⁻, ZnS:Pb, Cu, Zn₃(PO₄)₂:Mn²⁺, Zn₂SiO₄:Mn²⁺, Zn₂SiO₄:Mn²⁺, As⁵⁺, Zn₂SiO₄:Mn, Sb₂O₂, Zn₂SiO₄:Mn²⁺, P, Zn₂SiO₄:Ti⁴⁺, ZnS:Sn²⁺, ZnS:Sn, Ag, ZnS:Sn²⁺, Li⁺, ZnS:Te, Mn, ZnS—ZnTe:Mn²⁺, ZnSe:Cu⁺, Cl and ZnWO₄.

In general, the use of an emission-converting material offers the advantage of a wider emission spectrum of colours. Especially, by a combination of several phosphors the colour rendering of the LEDs can be improved. LEDs made from different phosphor emission-converting materials can be used for warm white LEDs from 2700K CCT to cold white LEDs at 5000K CCT.

As mentioned above, the phosphors according to the present invention can be excited over a broad range, extending from about 300 nm to 500 nm.

Accordingly, the present invention also relates to the use of at least one compound according to the present invention as conversion phosphor for the partial or complete conversion of the blue or near UV emission from a luminescent diode.

The present invention also relates to a light source, comprising a primary light source with an emission maximum in the range of 300 nm to 500 nm, and all or some of this radiation is converted into longer-wavelength radiation by a compound or an emission-converting material in accordance with the present invention.

Preferably, the illumination unit comprises a blue or near UV LED and at least one compound according to the present invention. Such illumination unit is preferably white-light-emitting, in particular having a colour coordinate of CIE x=0.12-0.43 and CIE y=0.07-0.43, more preferably CIE x=0.15-0.35 and CIE y=0.10-0.35,

Preference is furthermore given to an illumination unit, in particular for general lighting, which is characterised in that it has a CRI>60, preferably >70, more preferably >80.

In another embodiment, the illumination unit emits light having a certain colour point (colour-on-demand principle). The colour-on-demand concept is taken to mean the production of light having a certain colour point using a pcLED (=phosphor-converted LED) using one or more phosphors. This concept is used, for example, in order to produce certain corporate designs, for example for illuminated company logos, trademarks, etc.

Especially for the purpose that certain colour spaces should be established, the phosphor is preferably mixed with at least one further phosphor selected from the group of oxides, molybdates, tungstates, vanadates, garnets, silicates, sulfides, aluminates, nitrides and oxynitrides, in each case individually or mixtures thereof with one or more activator ions, such as Ce, Eu, Yb, Mn, Cr and/or Bi.

Suitable green emitting phosphors, are preferably selected from Ce-doped lutetium-containing garnets or yttrium-containing garnets, Eu-doped sulfoselenides, thiogallates, BaMgAl₁₀O₁₇: Eu, Mn (BAM: Eu, Mn), and/or Ce- and/or Eu-doped nitride containing phosphors and/or β-SiAlON: Eu, and/or Eu-doped alkaline earth ortho-silicates, and/or Eu-doped alkaline earth oxy-ortho-silicates, and/or Zn-doped alkaline earth ortho-silicates.

Suitable blue-emitting phosphor, are preferably selected from BAM: Eu and/or Sr₁₀(PO₄)₆Cl₂:Eu, and/or CaWO₄, and/or ZnS:(Au, Cu, Al), and/or Sr₄Al₁₄O₂₅:Eu, and/or Sr₅(PO₄)₃Cl:Eu, and/or Sr₂P₂O₇:Eu.

Suitable phosphors emitting yellow light, can preferably be selected from garnet phosphors (e.g., (Y,Tb,Gd)₃(Al,Ga)₅O₁₂:Ce), ortho-silicate phosphors (e.g., (Ca,Sr,Ba)₂SiO₄: Eu), sulfide phosphors (e.g. (Mg,Ca,Sr,Ba)S:Eu) and/or Sialon-phosphors (e.g., α-SiAlON: Eu), and/or (Ca,Sr, Ba)AlSi₄N₇:Ce.

The term “blue-emitting phosphor” refers to a phosphor emitting a wavelength having at least one emission maximum between 435 nm and 507 nm.

The term “green emitting phosphor” refers to a phosphor emitting a wavelength having at least one emission maximum between 508 nm and 550 nm.

The term “yellow emitting phosphor” or refers to a phosphor emitting a wavelength having at least one emission maximum between 551 nm and 585 nm.

The term “red-emitting phosphor” refers to a phosphor emitting a wavelength having at least one emission maximum between 586 and 670 nm.

In a preferred embodiment, the illumination unit according to the invention comprises a light source, which is a luminescent indium aluminium gallium nitride, in particular of the formula InᵢGaⱼAlₖN, where 0≦i, 0≦j, 0≦k, and i+j+k=1 and/or a light source, which is a luminescent indium gallium nitride (InxGa1-xN, where 0<x<0.4).

In a another preferred embodiment of the illumination unit according to the invention, the light source is a luminescent arrangement based on ZnO, TCO (transparent conducting oxide), ZnSe or SiC or an arrangement based on an organic light-emitting layer (OLED).

In a further preferred embodiment of the illumination unit according to the invention, the light source is a source which exhibits electroluminescence and/or photoluminescence. The light source may furthermore also be a plasma or discharge source. Possible forms of light sources of this type are known to the person skilled in the art. These can be light-emitting LED chips of various structures.

The compounds according to the present invention can either be dispersed in a resin (for example epoxy or silicone resin) or, in the case of suitable size ratios, arranged directly on the light source or alternatively arranged remote there from, depending on the application (the latter arrangement also includes “remote phosphor technology”). The advantages of remote phosphor technology are known to the person skilled in the art and are revealed, for example, by the following publication: Japanese Journal of Appl. Phys. Vol. 44, No. 21 (2005). L649-L651.

The compounds according to the present invention are also suitable for converting parts of solar irradiation having a wavelength of less than approximately 500 nm into radiation of a wavelength of more than approximately 500 nm, which can be utilized more effectively by a variety of semiconductor materials in solar cells.

Therefore, the present invention also relates to the use of at least one compound according to the invention as a wavelength conversion material for solar cells.

Thus, the invention relates also to a method of improvement of a solar cell module by applying e.g. a polymer film comprising a phosphor according to the present invention, which is capable to increase the light utilization efficiency and the power-generating efficiency, due to a wavelength conversion of the shortwave part of the solar irradiation spectrum which normally cannot be utilized due to the absorption characteristics of the semiconductor material in the solar cell module.

The present invention is described above and below with particular reference to the preferred embodiments. It should be understood that various changes and modifications might be made therein, without departing from the spirit and scope of the invention.

Many of the compounds or mixtures thereof as mentioned above and below, are commercially available. The organic compounds are either known or can be prepared by methods which are known per se, as described in the literature (for example in the standard works such as Houben-Weyl, Methoden der Organischen Chemie [Methods of Organic Chemistry], Georg-Thieme-Verlag, Stuttgart), to be precise under reaction conditions which are known and suitable for said reactions. Use may also be made here of variants which are known per se, but are not mentioned here.

Unless the context clearly indicates otherwise, as used herein plural forms of the terms herein are to be construed as including the singular form and vice versa.

Throughout this application, unless explicitly stated otherwise, the parameter ranges include all rational and integer numbers, including the specified limits of the parameter ranges as well as their error limits. The stated upper and lower limits for the respective ranges lead in combination with additional preferred ranges to other preferred embodiments.

Throughout this application, unless explicitly stated otherwise, all concentrations are given in weight percent and relate to the respective complete mixture, all temperatures are given in degrees centigrade (Celsius) and all differences of temperatures in degrees centigrade.

Throughout the description and claims of this specification, the words “comprise” and “contain” and variations of the words, for example “comprising” and “comprises”, mean “including but not limited to”, and are not intended to (and do not) exclude other components. On the other hand, the word “comprise” also encompasses the term “consisting of” but is not limited to it.

It will be appreciated that variations to the foregoing embodiments of the invention can be made while still falling within the scope of the invention. Alternative features serving the same, equivalent, or similar purpose may replace each feature disclosed in this specification, unless stated otherwise. Thus, unless stated otherwise, each feature disclosed is only one example of a generic series of equivalent or similar features.

All of the features disclosed in this specification may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

It will be appreciated that many of the features described above, particularly of the preferred embodiments, are inventive in their own right and not just as part of an embodiment of the present invention. Independent protection may be sought for these features in addition to, or alternative to any invention presently claimed.

The invention will now be described in more detail by reference to the following examples, which are illustrative only and do not limit the scope of the invention.

### Examples

### 1. LaBaMg₂Al₃Si₃N₂O₁₂:Eu

2 g La₂O₃, 1.9 g Al₂O₃, 2.1 g MgCO₃, 3.36 g BaCO₃, 0.87 g Si₃N₄, 1.12 g SiO₂, 0.26 g Eu₂O₃ are mixed in an agate mortar. The resulting mixture is fired at 1200° C. in ammonia (NH₃) atmosphere for 8 hours. Subsequently the powder obtained is grounded and re-calcined using the same conditions.

### 2. LaBaMg₂Al₃Si₂GeN₂O₁₂:Eu

2 g La₂O₃, 1.9 g Al₂O₃, 2.1 g MgCO₃, 2.36 g BaCO₃, 0.87 g Si₃N₄, 0.75 g SiO₂, 0.65 g GeO₂, 0.26 g Eu₂O₃ are mixed in an agate mortar. The resulting mixture is fired at 1200° C. in ammonia (NH₃) atmosphere for 8 hours. Subsequently the powder obtained is grounded and re-calcined using the same conditions.

### 3. LaBaCa₂Al₃Si₃N₂O₁₂:Eu

2 g La₂O₃, 1.9 g Al₂O₃, 2.5 g CaCO₃, 2.36 g BaCO₃, 0.87 g Si₃N₄, 1.12 g SiO₂, 0.26 g Eu₂O₃ are mixed in an agate mortar. The resulting mixture is fired at 1200° C. in ammonia (NH₃) atmosphere for 8 hours. Subsequently the powder obtained is grounded and re-calcined using the same conditions.

### 4. LaBaCa₂Al₃Si₂GeN₂O₁₂:Eu

2 g La₂O₃, 1.9 g Al₂O₃, 2.5 g CaCO₃, 2.36 g BaCO₃, 0.87 g Si₃N₄, 0.75 g SiO₂, 0.65 g GeO₂, 0.26 g Eu₂O₃ are mixed in an agate mortar. The resulting mixture is fired at 1200° C. in ammonia (NH₃) atmosphere for 8 hours. Subsequently the powder obtained is grounded and re-calcined using the same conditions.

### 5. LaBaCa₂Al₃SiGe₂N₂O₁₂:Eu

2 g La₂O₃, 1.9 g Al₂O₃, 2.5 g CaCO₃, 2.36 g BaCO₃, 0.87 g Si₃N₄, 0.37 g SiO₂, 1.3 g GeO₂, 0.26 g Eu₂O₃ are mixed in an agate mortar. The resulting mixture is fired at 1200° C. in ammonia (NH₃) atmosphere for 8 hours. Subsequently the powder obtained is grounded and re-calcined using the same conditions.

### I. LED Examples of LaBaMg₂Al₃Si₃N₂O₁₂:Eu

10 mg of LaBaMg₂Al₃Si₃N₂O₁₂:Eu are mixed with a mixture of silicone and a curing agent (1:1) (15 mg). The obtained suspension (25 mg) is homogenized and applied onto an LED chip (395 nm near-UV chip). The LED with the suspension is placed in an oven and heated for 4 hours at 100° C. in order to facilitate the curing process. Afterwards, the finished LED is cooled down and used for the measurements. As the LED chip has only a minor emission contribution in the visible region, the color point obtained in general is independent on the amount of the phosphor used. The amount of the phosphor used has influence on the conversion of the primary light (395 nm) into the visible light (phosphor emission).

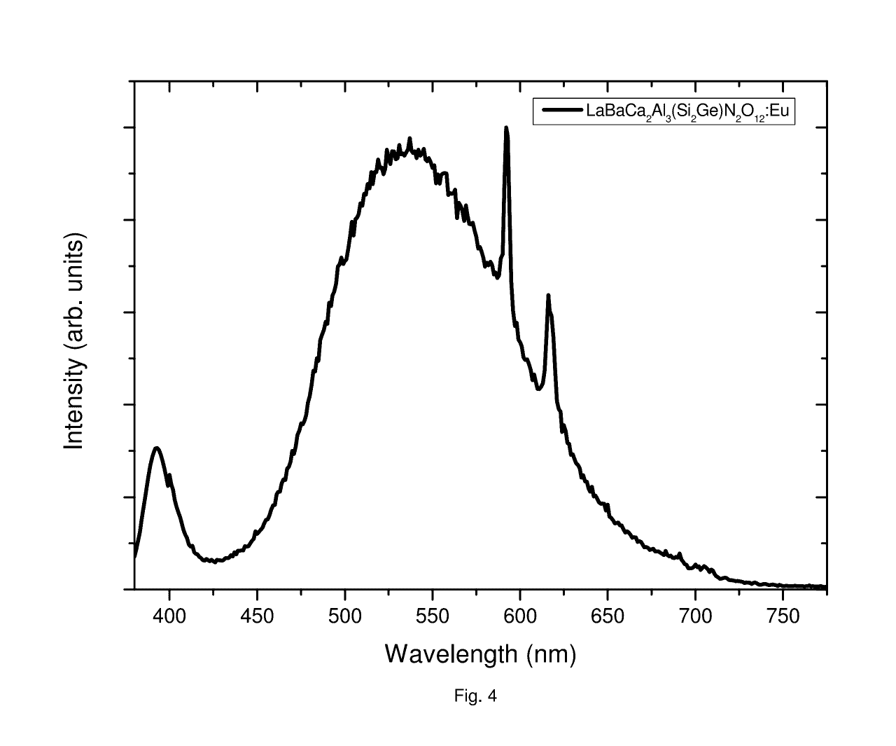

FIG. 4 shows an example LED spectrum of LaBaMg₂Al₃Si₃N₂O₁₂:Eu in a near UV LED emitting primary light source at 395 nm.

### II. LED Examples of LaBaMg₂Al₃Si₂GeN₂O₁₂:Eu

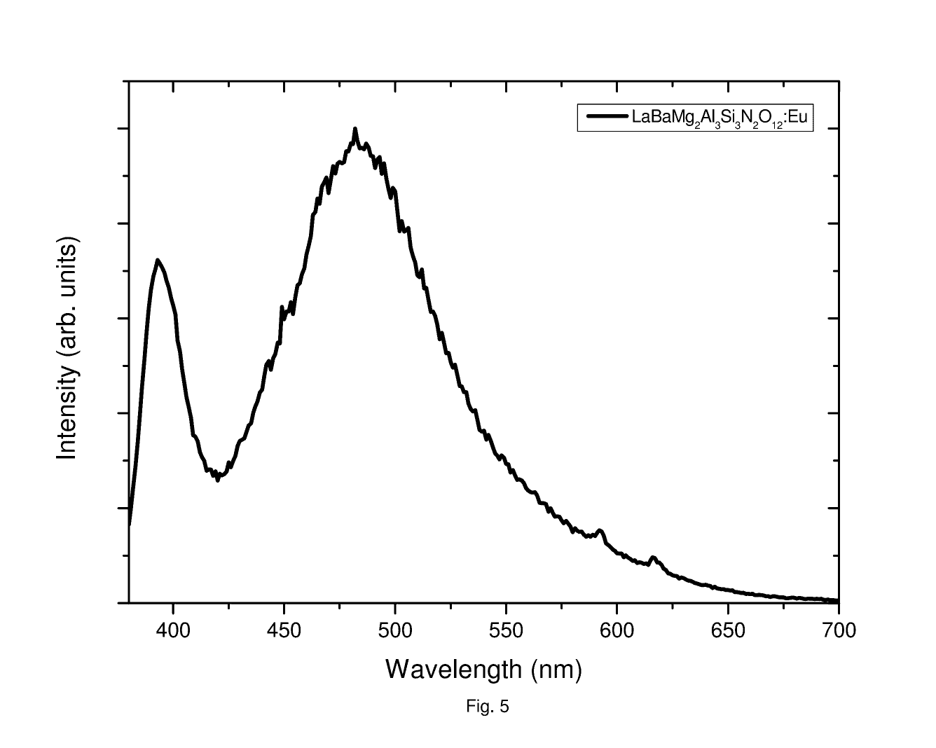

In the same manner as described above, LaBaMg₂Al₃(Si₂,Ge)N₂O₁₂:Eu is combined with a near UV LED emitting primary light source at 395 nm FIG. 5 shows an example LED spectrum of LaBaMg₂Al₃(Si₂,Ge)N₂O₁₂:Eu.

1. Compound of formula I,
M^{I}M^{II}₃ M^{III}₃M^{IV}₃N₂O₁₂:Eu I
wherein
M^{I} denotes one or more elements selected from Y, La, Gd and Lu,
M^{II} denotes one or more elements selected from the group of Be, Mg, Ca, Sr, Ba and/or Zn.
M^{III} denotes one or more elements selected from the group of B, Al, and Ga,
M^{IV} denotes one or more elements selected from the Si and Ge.

2. The compound according to claim 1, characterized in that the compound is selected from the group of compounds of formula II,
M^{I}M^{II}₃ M^{III}₃M^{IV}₃N₂O₁₂:Eu²⁺ II
wherein
M^{I}, M^{II}, M^{III}, M^{IV} have the same meanings as given in claim 1.

3. The compound according to claim 1, characterized in that the compound is selected from the group of compounds of formula III,
M^{I}M^{II}₃₋ₓ M^{III}₃M^{IV}₃N₂O₁₂:Eu²⁺ₓ III
wherein
M^{I}, M^{II}, M^{III}, and M^{IV} have the same meanings as given in claim 1, and 0<x<3.

4. The compound according to claim 1, wherein M^{I} denotes La.

5. The compound according to claim 1, wherein M^{III} denotes Al.

6. The compound according to claim 1, wherein M^{IV} denotes (Ge_{1-y}Si_{y}) wherein 0≦y≦1.

7. The compound according to claim 1, wherein M^{II} denotes at least one element selected from Mg, Ca, Sr, and/or Ba.

8. The compound according to claim 1, wherein M^{II} denotes (Ba_{1-z} EA_{z}) in which 0≦z≦1, and EA denotes at least one element selected from Mg, Ca and Sr.

9. The compound according to claim 2, characterized in that 0<x≦0.3.

10. A process for the preparation of a compound according to claim 1, comprising at least the steps a) mixing of suitable starting materials or corresponding reactive forms thereof, and b) thermal treatment of the mixture under reductive conditions.

11. The process according to claim 10, wherein the salts in step a) are selected from the group of oxides, halides, or carbonates and at least one binary nitride.

12. A method for the partial or complete conversion of a blue or near UV-emission comprising using a compound according to claim 1 as a conversion phosphor.

13. An emission-converting material comprising at least one compound according to claim 1.

14. A light source, comprising a primary light source with an emission maximum in the range of 300 nm to 500 nm, and a compound according to claim 1.

15. The light source according to claim 14 wherein the primary light source is a luminescent indium aluminium gallium nitride, and/or indium gallium nitride.

16. An Illumination unit comprising at least one light source according to claim 14.
